(19) United States
(12) Patent Application Publication
(10) Pub. No.: US 2006/0008709 A1
(43) Pub. Date: Jan. 12, 2006

(54) Mask and method for determining mask pattern line length

(75) Inventors: Yasuyuki Kushida, Kawasaki (JP); Hitoshi Handa, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/009,039

(22) Filed: Dec. 13, 2004

(30) Foreign Application Priority Data
Jul. 12, 2004 (JP) 2004-204053

(51) Int. Cl. G03C 5/00; G03F 1/00

(52) U.S. Cl. 430/5; 430/311; 430/312; 430/394; 430/313

(57) ABSTRACT

A mask on which the line length of a mask pattern can be determined with great accuracy. Auxiliary patterns used for determining line length are formed near edges of a pattern to be determined. The position of the edges of the pattern to be determined is determined on the basis of the auxiliary patterns and the amount of a shift in the position of the edges of the pattern to be determined from a designed value is determined. By doing so, the line length of the pattern to be determined is found. The auxiliary patterns are formed so that their shape, line length, and positions will not exert an influence upon functions which a circuit pattern formed on a wafer by transferring the pattern to be determined should originally have.

### CROSS-REFERENCE TO RELATED APPLICATIONS

This application is based upon and claims the benefits of priority from the prior Japanese Patent Application No. 2004-204053, filed on Jul. 12, 2004, the entire contents of which are incorporated herein by reference.

### BACKGROUND OF THE INVENTION

(1) Field of the Invention

This invention relates to a mask and a method for determining the line length of a mask pattern and, more particularly, to a mask used for forming a circuit pattern in a semiconductor device and a method for determining the line length of a mask pattern formed on such a mask.

(2) Description of the Related Art

In recent years semiconductor devices have become minute and their integration levels have become high. Accordingly, there have been severer demands for accuracy in the line length of mask patterns formed on photo masks (masks) used for fabricating them.

Usually items for guaranteeing the line length of a mask pattern include within-mask uniformity, linearity, a proximity effect, and X-Y difference. In addition to them, in recent years great importance has been attached to the amount of a shift of the position of an edge of a mask pattern from a designed value in masks for advanced devices. The reason for this is that in device fabrication a circuit pattern portion formed by transferring an edge portion of a line pattern onto a wafer often overlaps with a hole pattern for connecting the circuit pattern portion to another layer with the circuit pattern portion as a wiring edge. For example, if a device is fabricated with a mask on which the amount of a shift of the position of an edge of a line pattern is large, it may be impossible to ensure a sufficient contact area between the line pattern and a hole pattern. In this case, the contact will be bad.

At present the integration levels of advanced devices become higher and the number of their functions increases. This leaves no extra space in writing lines and contact holes at design time. Therefore, mask patterns must be formed with great accuracy on masks used for forming circuit patterns in devices. Meanwhile, when mask patterns are formed on masks, the positions of the edges of the mask patterns may shift from their designed values. Therefore, to fabricate high-quality devices, the line length of mask patterns formed on masks must be determined in advance with great accuracy and must be guaranteed.

Conventionally, scanning electron microscopes (SEMs) have widely been used for determining the line length of mask patterns. When the line length of mask patterns is determined with SEMs, the upper limit of line length which can be determined on SEM screens is about 3 μm at magnification (50,000, for example) necessary for ordinary accuracy guarantees.

FIG. 11 shows an example of a mask pattern.

It is assumed that a device includes a layer on which a circuit pattern having a shape shown in FIG. 11 is formed and that the longer line length (about 2.5 to 3.0 μm) of a mask pattern 100 used for forming the circuit pattern must be guaranteed. In such a case, the entire mask pattern 100 is displayed on a SEM screen and line length L from the left end to the right end will be determined. In certain circumstances, the magnification of the SEM is lowered, the entire mask pattern 100 is displayed on the SEM screen, and its line length is determined.

The above-mentioned use is a simple example and SEMs are used for, for example, determining the line length of circuit patterns after exposure. For example, a method for forming a pattern with long line length for detecting a shift in position used for determining a shift in position with an optical measuring apparatus and a pattern with short line length for detecting a shift in position used for determining a shift in position with a SEM is proposed (see, for example, Japanese Unexamined Patent Publication No. Hei 11-297588).

### SUMMARY OF THE INVENTION

A mask having a mask pattern is provided by the present invention. This mask has auxiliary patterns near the mask pattern used for determining the line length of the mask pattern.

In addition, a method for determining the line length of a mask pattern is provided by the present invention. In this method for determining the line length of a mask pattern, the line length of the mask pattern is found by determining the position of the mask pattern in respect to auxiliary patterns located near the mask pattern.

The above and other features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 is a plan view showing the structure of a main portion of a mask.

FIG. 2 is a view for describing a method for determining the line length of a mask pattern.

FIG. 3 is a plan view of a main portion of an evaluation mask used for doing simulations of light intensity.

FIG. 4 shows results obtained by doing simulations of light intensity for a binary mask on which S=0.1 μm.

FIG. 5 shows results obtained by doing simulations of light intensity for a binary mask on which S=0.2 μm.

FIG. 6 shows results obtained by doing simulations of light intensity for a binary mask on which S=0.3 μm.

FIG. 7 shows results obtained by doing simulations of light intensity for a half tone mask on which S=0.1 μm.

FIG. 8 shows results obtained by doing simulations of light intensity for a half tone mask on which S=0.2 μm.

FIG. 9 shows results obtained by doing simulations of light intensity for a half tone mask on which S=0.3 μm.

FIG. 10 is a plan view showing the structure of a main portion of a mask on which an isolated pattern is formed.

FIG. 11 shows an example of a mask pattern.

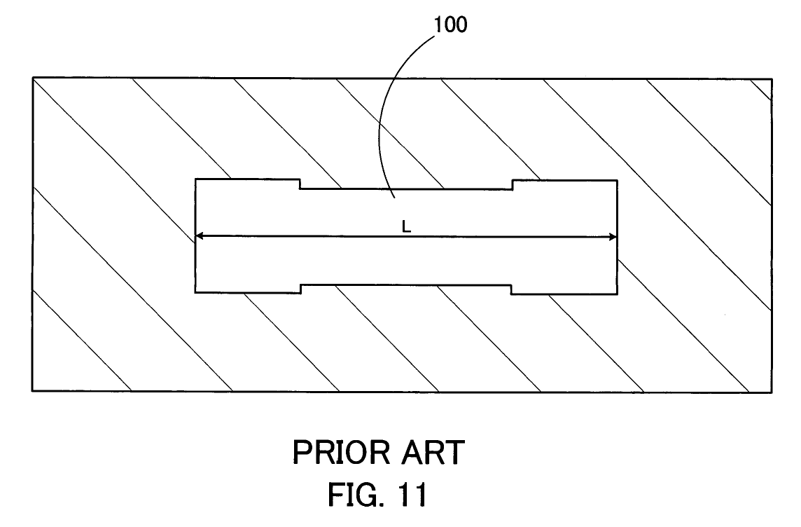

FIG. 12 shows another example of a mask pattern.

### DESCRIPTION OF THE PREFERRED EMBODIMENTS

As described in the “Description of the Related Art,” in the conventional method for determining the line length of a mask pattern with a SEM, an error in the line length of a mask pattern determined may be caused by problems, such as the repeatability of difference in line length in a screen, a change with the passage of time in line length, and a change with the passage of time in difference in line length between magnifications.

The problem of the repeatability of difference in line length in a screen is as follows. For example, there is a difference between a value obtained by determining the line length of a mask pattern displayed in the center of a SEM screen and a value obtained by determining the line length of the mask pattern displayed at the edge of the SEM screen, and this difference is not repeatable. When the whole of one mask pattern is displayed on a screen, both ends of the mask pattern may be at the edges of the screen, depending on the magnification of the SEM. Therefore, a value obtained by determining the distance between both ends of the mask pattern may differ from the actual value.

The problem of a change with the passage of time in line length is as follows. A value obtained by determining the line length of the same mask pattern varies each time determination is made (from determination date to determination date, for example). The larger the size of a mask pattern becomes, the larger the amount of a change with the passage of time in line length becomes. This is based on the principle of SEM calibration.

The problem of a change with the passage of time in difference in line length between magnifications is as follows. A value obtained by determining the line length of the same mask pattern varies when the magnification of the SEM is changed. In addition, difference in line length between magnifications varies each time determination is made (from determination date to determination date, for example). Therefore, when the magnification of the SEM is lowered to a value smaller than an ordinary value so that the entire mask pattern will be displayed on the screen, a value obtained by determining the line length of the mask pattern at this magnification may differ from a value obtained by determining the line length of the mask pattern at the ordinary magnification. In this state of things it is impossible to compare the line length of this mask pattern with that of another mask pattern.

In the conventional method for determining the line length of a mask pattern with a SEM, these factors often exert an influence simultaneously. Moreover, it is very difficult to separate or specify these factors. Therefore, even if the mask pattern is formed to design, a determination error may occur because of the SEM, being an apparatus for determining line length. As a result, it is possible that the line length of the mask pattern obtained will not be correct.

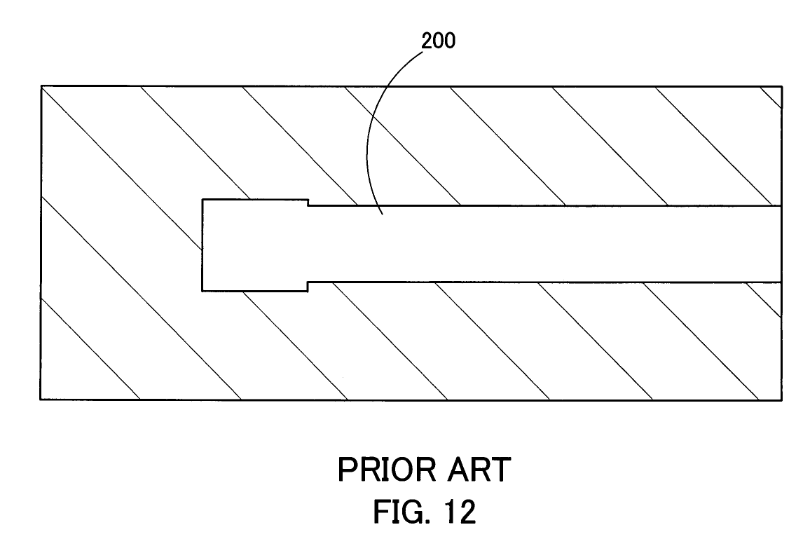

FIG. 12 shows another example of a mask pattern.

Mask patterns formed on masks include an isolated pattern 200 around which other mask patterns do not exist. Essentially, the position of the edge of the isolated pattern 200 must also be guaranteed.

Even if the whole of a mask pattern cannot be displayed on a SEM screen at predetermined magnification, it is possible in some cases to grasp the position of the edge of the mask pattern in respect to a second mask pattern around the edge by displaying the edge and the second mask pattern at the magnification.

With the isolated pattern 200, however, a second mask pattern which can be used as a standard does not exist around it. Accordingly, the position of the edge of the isolated pattern 200 cannot be grasped. If the magnification of the SEM is lowered to display the isolated pattern 200 and another mask pattern, the above-mentioned problem of a difference in line length between magnifications or the like will occur. That is to say, under the present conditions, it is virtually impossible to guarantee accuracy in determining the line length of the isolated pattern 200.

The present invention was made to solve such a problem. An object of the present invention is to provide a mask on which the line length of a mask pattern can be determined with great accuracy and a method for determining the line length of such a mask pattern.

Embodiments of the present invention will now be described in detail with reference to the drawings.

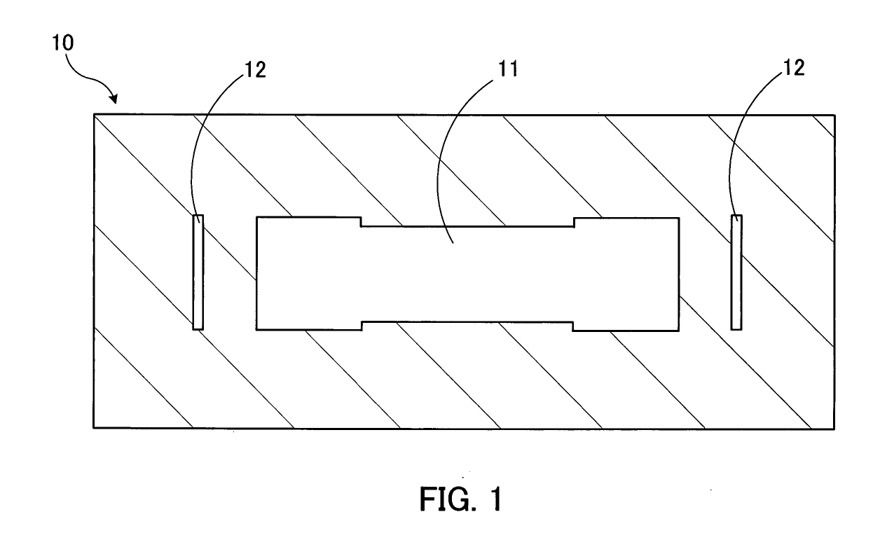

FIG. 1 is a plan view showing the structure of a main portion of a mask.

With a mask 10 shown in FIG. 1, a light shielding film of chromium (Cr) or molybdenum silicide (MoSi) is formed on a glass substrate made from, for example, silica. That is to say, light transmitting portions which transmit light at the time of transferring onto a wafer and light shielding portions which shield light at the time of transferring onto a wafer are formed on the mask 10. A pattern 11 to be determined the line length of which is to be determined and minute auxiliary patterns 12 which are formed near the edges of the pattern 11 to be determined and which are used for determining the line length of the pattern 11 to be determined are the light transmitting portions of the mask 10.

The pattern 11 to be determined corresponds to a circuit pattern transferred onto a wafer in the fabrication of a device.

The auxiliary patterns 12 are formed so that their shape, line length, and positions will not exert an influence upon functions which the circuit pattern formed on the wafer by transferring the pattern 11 to be determined should originally have.

Accordingly, it is preferable that the auxiliary patterns 12 the line length of which does not exert an influence upon the line length of the circuit pattern formed by transferring the pattern 11 to be determined should be formed at appropriate positions. Moreover, it is preferable that the auxiliary patterns 12 should not be transferred onto the wafer. Therefore, when the mask 10 is designed, the line length of the auxiliary patterns 12 and the distance between the auxiliary patterns 12 and the pattern 11 to be determined must adequately be considered. The line length of the auxiliary patterns 12 and the distance between the pattern 11 to be determined and the auxiliary patterns 12 will be described later in detail.

The pattern 11 to be determined and the auxiliary patterns 12 are formed in this way. As a result, after the mask 10 is fabricated, the line length of the pattern 11 to be determined can be obtained with great accuracy by determining the distance between the pattern 11 to be determined and the auxiliary patterns 12 with a SEM. A method for determining the line length of the mask pattern formed on the mask 10 by using a SEM will now be described.

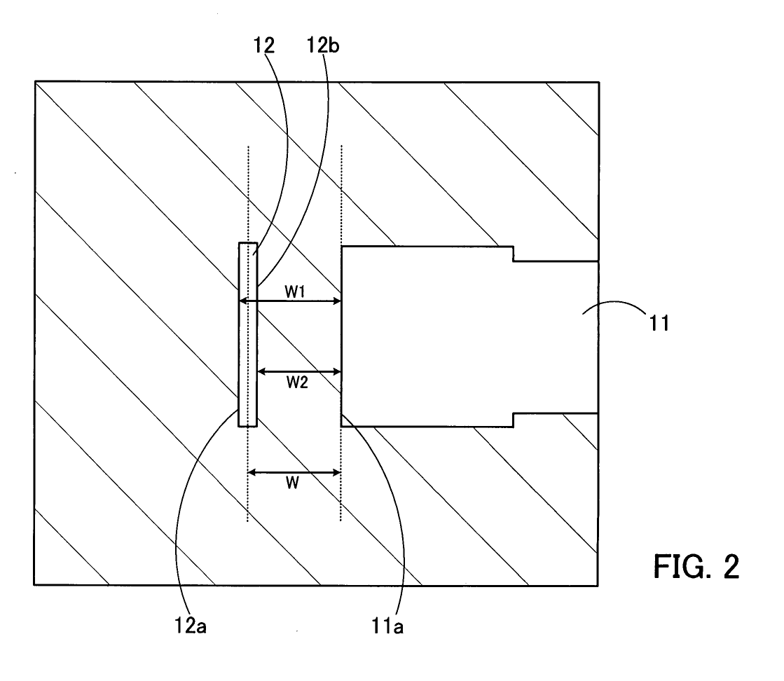

FIG. 2 is a view for describing a method for determining the line length of the mask pattern.

To determine the line length of the pattern 11 to be determined, a distance W1 between an edge (edge opposite the auxiliary pattern 12) 11a of the pattern 11 to be determined and a left-hand edge (far edge from the pattern 11 to be determined) 12a of the auxiliary pattern 12 is determined first.

Then a distance W2 between the edge 11a of the pattern 11 to be determined and a right-hand edge (near edge from the pattern 11 to be determined) 12b of the auxiliary pattern 12 is determined in the same way.

A distance W (=(W1+W2)/2) between the edge 11a of the pattern 11 to be determined and the position of the center of gravity (position of the midpoint between the edges 12a and 12b) of the auxiliary pattern 12 is calculated.

After the distance W is calculated in this way, the difference (=W−W′) between the distance W and a designed value W′ of the distance between the edge 11a of the pattern 11 to be determined and the position of the center of gravity of the auxiliary pattern 12 is calculated. This difference corresponds to the amount of a shift in the position of the edge 11a of the pattern 11 to be determined.

The amount of a shift in the position of the edge 11a of the pattern 11 to be determined can be calculated by using one of the distances W1 and W2 as the distance between the pattern 11 to be determined and the auxiliary pattern 12. As described above, however, by calculating the distance W on the basis of the position of the center of gravity of the auxiliary pattern 12, the influence of an error in the line length of the auxiliary pattern 12 itself can be eliminated.

In FIG. 2, only one edge portion of the pattern 11 to be determined is shown. However, the same process that is described above is performed on the other edge portion of the pattern 11 to be determined shown in FIG. 1. That is to say, by finding the position of the other edge of the pattern 11 to be determined in respect to the auxiliary pattern 12 opposite it, the amount of a shift in the position of the other edge of the pattern 11 to be determined is calculated. Then the line length of the pattern 11 to be determined is found from the amount of shifts of the positions of both edges of the pattern 11 to be determined.

By locating the auxiliary patterns 12 near both edges of the pattern 11 to be determined in this way, shifts of the positions of both edges of the pattern 11 to be determined can be quantified with great accuracy and the line length of the pattern 11 to be determined can be found with accuracy.

Moreover, by locating the auxiliary patterns 12, the amount of shifts of the positions of both edges of the pattern 11 to be determined can be determined with the auxiliary patterns 12 and both edge portions of the pattern 11 to be determined displayed near the center of the screen. This significantly reduces the amount of a determination error caused by a difference in line length in a screen.

The auxiliary patterns 12 are minute, so the amount of a change with the passage of time in line length which occurs as a result of using a SEM can be reduced. Therefore, the amount of a determination error caused by a change with the passage of time in line length can be reduced significantly.

In addition, even if the line length of the pattern 11 to be determined is about 2.5 to 3.0 μm, that is to say, even if the pattern 11 to be determined is comparatively large, the line length of the pattern 11 to be determined can be determined at the same magnification that is used for another mask pattern with a line length of about 1 μm with both edge portions of the pattern 11 to be determined displayed near the center of the screen. This eliminates determination errors caused by a difference in line length between magnifications and a change of it with the passage of time.

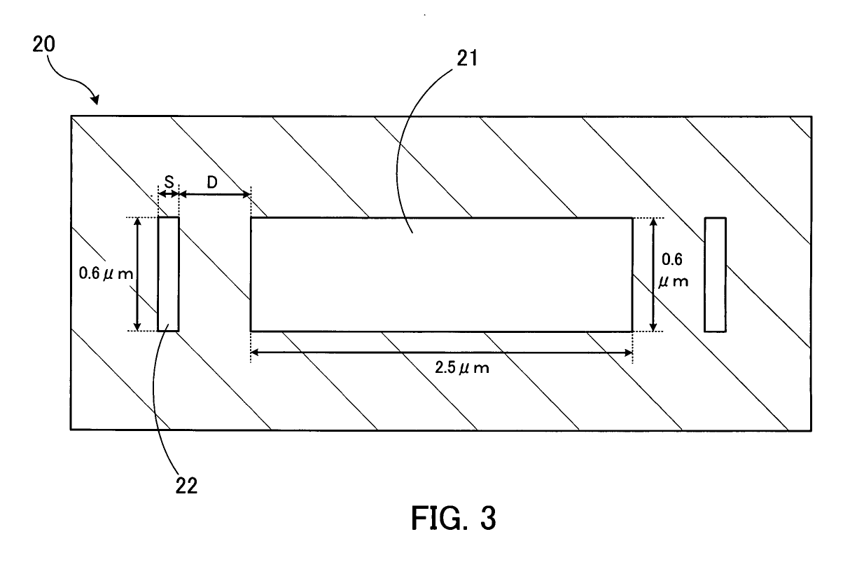

The line length of the auxiliary patterns 12 and the distance between the pattern 11 to be determined and the auxiliary patterns 12 that must be considered at the time of designing the mask 10 will now be described. In this case, simulations of light intensity are done with a mask pattern shown in FIG. 3 as an example.

FIG. 3 is a plan view of a main portion of an evaluation mask used for doing simulations of light intensity.

On an evaluation mask 20 shown in FIG. 3, a pattern 21 to be determined is formed and auxiliary patterns 22 are formed near both edges of the pattern 21 to be determined. The size of the pattern 21 to be determined is 0.6 μm×2.5 μm. The line length (S) of the auxiliary patterns 22 and the distance (D) between the edge of the pattern 21 to be determined and the edge of the auxiliary pattern 22 that do not exert an influence upon the line length of a circuit pattern formed by transferring the pattern 21 to be determined are found by doing simulations of light intensity. Simulation conditions are shown in Table 1.

TABLE 1

| | | | | | CONDITIONS FOR LOCATING | |
|---|---|---|---|---|---|---|
| | | EXPOSURE | | | AUXILIARY PATTERNS | |
| No. | MASK TYPE | WAVELENGTH | NA | σ | S (μm) | D (μm) |
| 1 | BINARY | ArF | 0.70 | 0.80 | 0.1, 0.2, 0.3 | 0.2, 0.4, 0.6, |
| | | | | | | 1.2, 2.4 |
| 2 | HALF TONE | ArF | 0.70 | 0.85/ | 0.1, 0.2, 0.3 | 0.2, 0.4, 0.6, |
| | | | | 0.425 | | 1.2, 2.4 |

Masks used are of two types. One is a binary mask (No. 1) on which Cr is used for forming a light shielding film and the other is a half tone phase shift mask (half tone mask) (No. 2) on which MoSi is used as a shifter. For both mask types, an exposure wavelength is 193 nm obtained by using an ArF exima laser as a light source. The transmittance of the half tone mask is about 6%. The numerical aperture (NA) of a lens is 0.70. The ratio (σ) of the NA of the lens to the NA of the light source is 0.80 for the binary mask and 0.85/0.425 for the half tone mask.

For both mask types, simulations are done with the line length (S) as 0.1 μm, 0.2 μm, or 0.3 μm and the distance (D) as 0.2 μm, 0.4 μm, 0.6 μm, 1.2 μm, or 2.4 μm. The values of the line length (S) and the distance (D) shown in Table 1 are those determined on the evaluation mask 20.

For both mask types, mask patterns are reduced at a magnification of ¼ and are transferred onto wafers when these simulations of light intensity are done.

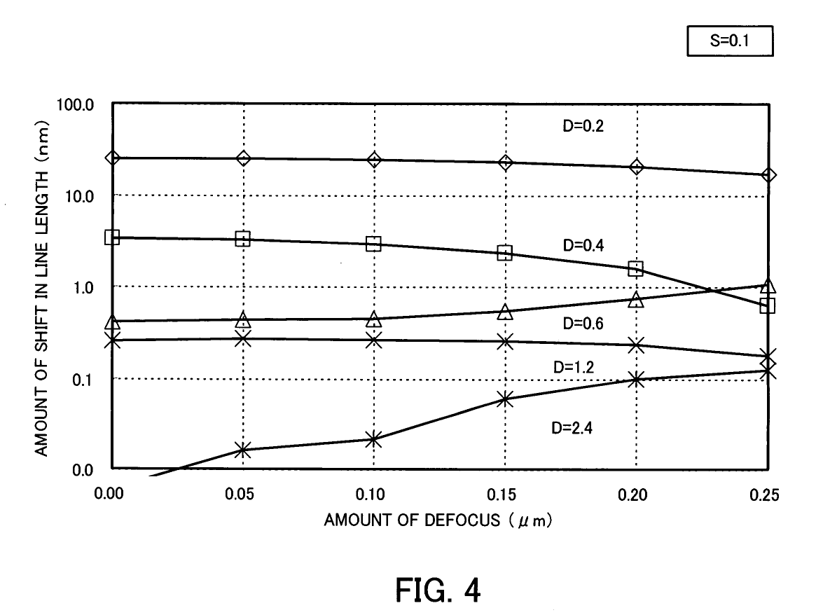

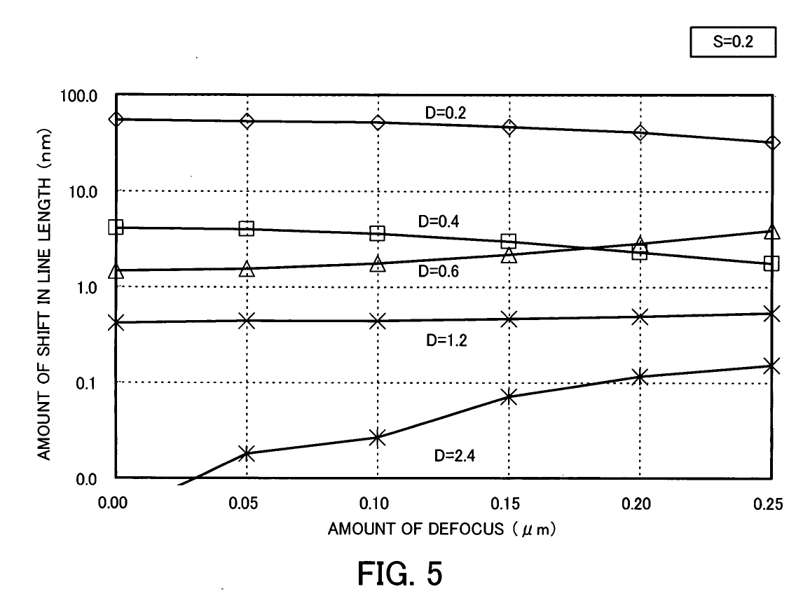

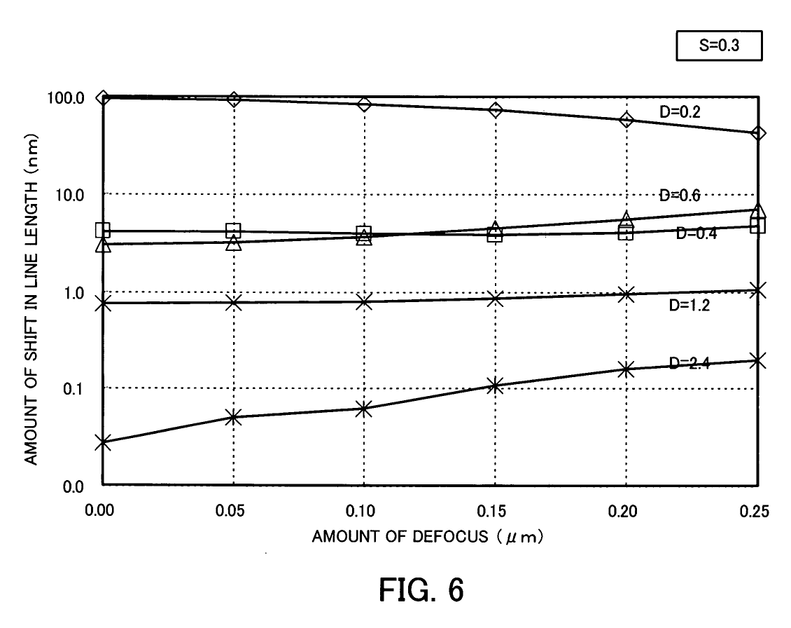

FIGS. 4 through 6 show results obtained by doing simulations of light intensity for binary masks. FIG. 4 shows results obtained by doing simulations of light intensity for a binary mask on which S=0.1 μm. FIG. 5 shows results obtained by doing simulation of light intensity for a binary mask on which S=0.2 μm. FIG. 6 shows results obtained by doing simulations of light intensity for a binary mask on which S=0.3 μm.

In each of FIGS. 4 through 6, a horizontal axis indicates the amount (in nm) of a defocus of an exposure apparatus and a vertical axis indicates the difference (in μm) between the line length of a circuit pattern formed on a wafer and the line length of a circuit pattern formed on a wafer without locating the auxiliary patterns 22. FIG. 4 shows the relationship between the amount of a defocus of the exposure apparatus and the difference between the line length of the circuit patterns which is obtained when the line length (S) is 0.1 μm and the distance (D) is 0.2 μm, 0.4 μm, 0.6 μm, 1.2 μm, or 2.4 μm. FIG. 5 shows the relationship between the amount of a defocus of the exposure apparatus and the difference between the line length of the circuit patterns which is obtained when the line length (S) is 0.2 μm and the distance (D) is 0.2 μm, 0.4 μm, 0.6 μm, 1.2 μm, or 2.4 μm. FIG. 6 shows the relationship between the amount of a defocus of the exposure apparatus and the difference between the line length of the circuit patterns which is obtained when the line length (S) is 0.3 μm and the distance (D) is 0.2 μm, 0.4 μm, 0.6 μm, 1.2 μm, or 2.4 μm.

As can be seen from the results of the light intensity simulations shown in FIGS. 4 through 6, conditions for locating the auxiliary patterns 22 which make the difference between the line length of the circuit patterns formed on the wafers zero do not exist. Accordingly, it is assumed that the allowable value of a total shift in the line length of a circuit pattern caused by locating the auxiliary patterns 22 is 1 nm or less. If a total shift in the line length of the circuit pattern is not greater than this allowable value, it is safe to consider that the auxiliary patterns 22 do not exert an influence upon the line length of the circuit pattern formed by transferring.

As can be seen from FIG. 4, a total shift in the line length of the circuit pattern is smaller than or equal to 1 nm when the line length (S) is 0.1 μm and the distance (D) is 0.6 μm, 1.2 μm, or 2.4 μm. As can be seen from FIG. 5, a total shift in the line length of the circuit pattern is smaller than or equal to 1 nm when the line length (S) is 0.2 μm and the distance (D) is 1.2 μm or 2.4 μm. As can be seen from FIG. 6, a total shift in the line length of the circuit pattern is smaller than or equal to 1 nm when the line length (S) is 0.3 μm and the distance (D) is 1.2 μm or 2.4 μm. Therefore, with the binary mask, conditions for locating the auxiliary patterns 22 are line length (S)≦0.3 μm and distance (D)≧1.2 μm.

If conditions for locating the auxiliary patterns 22 are considered from the viewpoint of the fabrication of a mask, the value of the line length (S) should be as great as possible so that a margin of pattern resolution can be ensured in the fabrication of the mask. The value of the distance (D) should be as small as possible so that the auxiliary patterns 22 will not be very far from the pattern 21 to be determined and so that the amount of a determination error which occurs as a result of using a SEM can be minimized. Therefore, with the binary mask, line length (S)=0.3 μm and distance (D)=1.2 μm can be obtained as conditions for properly locating the auxiliary patterns 22.

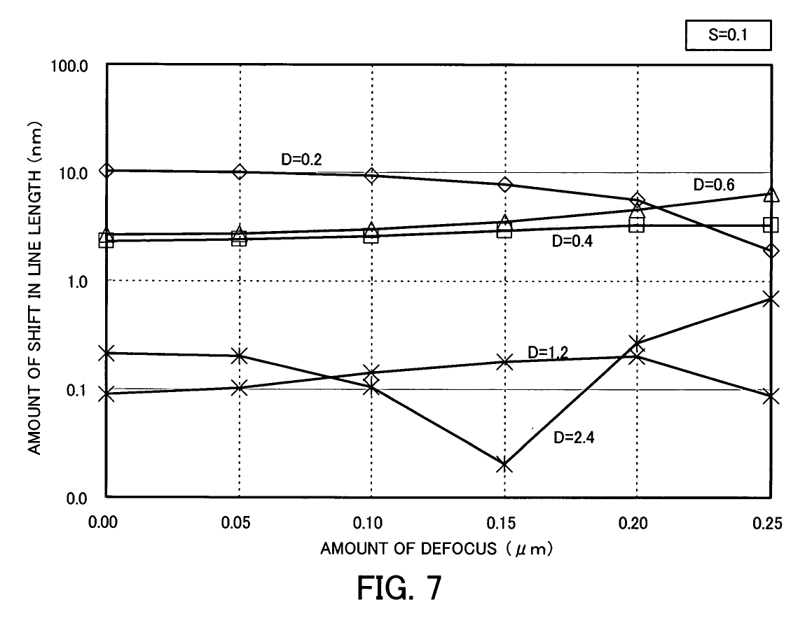

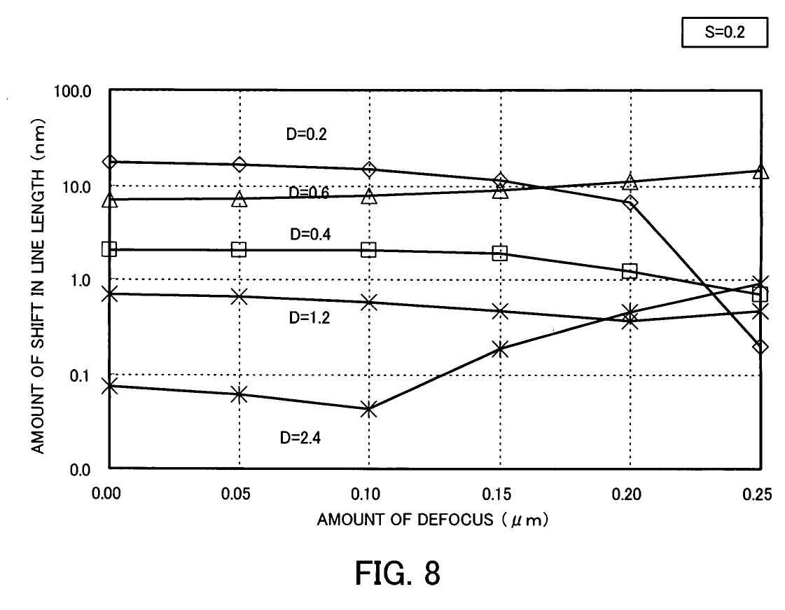

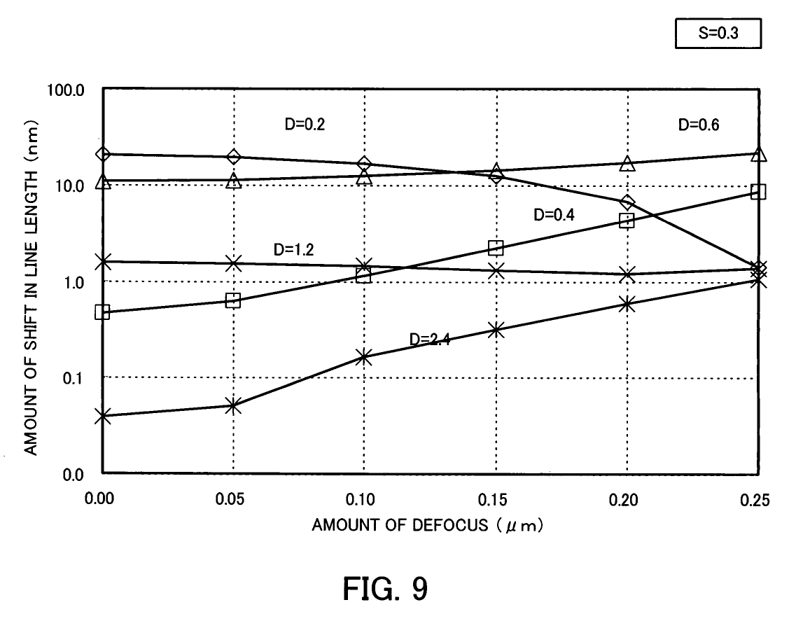

FIGS. 7 through 9 show results obtained by doing simulations of light intensity for half tone masks. FIG. 7 shows results obtained by doing simulations of light intensity for a half tone mask on which S=0.1 μm. FIG. 8 shows results obtained by doing simulations of light intensity for a half tone mask on which S=0.2 μm. FIG. 9 shows results obtained by doing simulations of light intensity for a half tone mask on which S=0.3 μm.

In each of FIGS. 7 through 9, a horizontal axis indicates the amount (in μm) of a defocus of the exposure apparatus and a vertical axis indicates the difference (in μm) between the line length of a circuit pattern formed on a wafer and the line length of a circuit pattern formed on a wafer without locating the auxiliary patterns 22. FIG. 7 shows the relationship between the amount of a defocus of the exposure apparatus and the difference between the line length of the circuit patterns which is obtained when the line length (S) is 0.1 μm and the distance (D) is 0.2 μm, 0.4 μm, 0.6 μm, 1.2 μm, or 2.4 μm. FIG. 8 shows the relationship between the amount of a defocus of the exposure apparatus and the difference between the line length of the circuit patterns which is obtained when the line length (S) is 0.2 μm and the distance (D) is 0.2 μm, 0.4 μm, 0.6 μm, 1.2 μm, or 2.4 μm. FIG. 9 shows the relationship between the amount of a defocus of the exposure apparatus and the difference between the line length of the circuit patterns which is obtained when the line length (S) is 0.3 μm and the distance (D) is 0.2 μm, 0.4 μm, 0.6 μm, 1.2 μm, or 2.4 μm.

As can be seen from the results of the light intensity simulations shown in FIGS. 7 through 9, conditions for locating the auxiliary patterns 22 which make the difference between the line length of the circuit patterns formed on the wafers zero do not exist. Accordingly, it is assumed that the allowable value of a total shift in the line length of a circuit pattern caused by locating the auxiliary patterns 22 is 1 nm or less. This is the same with the above-mentioned binary mask.

As can be seen from FIG. 7, a total shift in the line length of the circuit pattern is smaller than or equal to 1 nm when the line length (S) is 0.1 μm and the distance (D) is 1.2 μm or 2.4 μm. As can be seen from FIG. 8, a total shift in the line length of the circuit pattern is smaller than or equal to 1 nm when the line length (S) is 0.2 μm and the distance (D) is 1.2 μm or 2.4 μm. As can be seen from FIG. 9, a total shift in the line length of the circuit pattern is smaller than or equal to 1 nm when the line length (S) is 0.3 μm and the distance (D) is 2.4 μm.

Line length (S)=0.3 μm and distance (D)=2.4 μm are obtained as conditions for locating the auxiliary patterns 22 in a way that is the same with the binary mask. From the view point of determining line length, however, there is no advantage to locating the auxiliary patterns 22 at a place 2.4 μm distant from the pattern 21 to be determined the size of which is 0.6 μm×2.5 μm. This does not differ greatly from conventional methods. Therefore, with the half tone mask, line length (S)=0.2 μm and distance (D)=1.2 μm can be considered as conditions for properly locating the auxiliary patterns 22.

As stated above, conditions for properly locating the auxiliary patterns 22 in respect to the pattern 21 to be determined vary depending on which of the binary mask or the half tone mask is used. Basically, if the line length (S) is increased to stably fabricate a mask, then the distance (D) must also be increased to prevent a shift in the line length of a circuit pattern caused by light which passes through the auxiliary patterns 22. When the auxiliary patterns 22 are formed, this must be taken into consideration. As a result, it is necessary to set the line length (S) and the distance (D) for each pattern 21 to be determined according to the type of a mask used.

In the above examples, the results of the light intensity simulations obtained when a reduction magnification of ¼ is used at exposure time are shown. If this reduction magnification is changed, the conditions of the line length (S) and the distance (D) for the auxiliary patterns 22 must be reset.

By forming a mask on the basis of the above-mentioned simulations results of light intensity, the amount of a shift in the position of the edge of a pattern to be determined can be determined by using auxiliary patterns and the line length of the mask pattern can be determined with great accuracy.

Conventionally, it has been virtually impossible to determine the amount of a shift in the position of the edge of an isolated pattern. However, by forming the above-mentioned auxiliary patterns, the amount of a shift in the position of the edge of such an isolated pattern can also be determined.

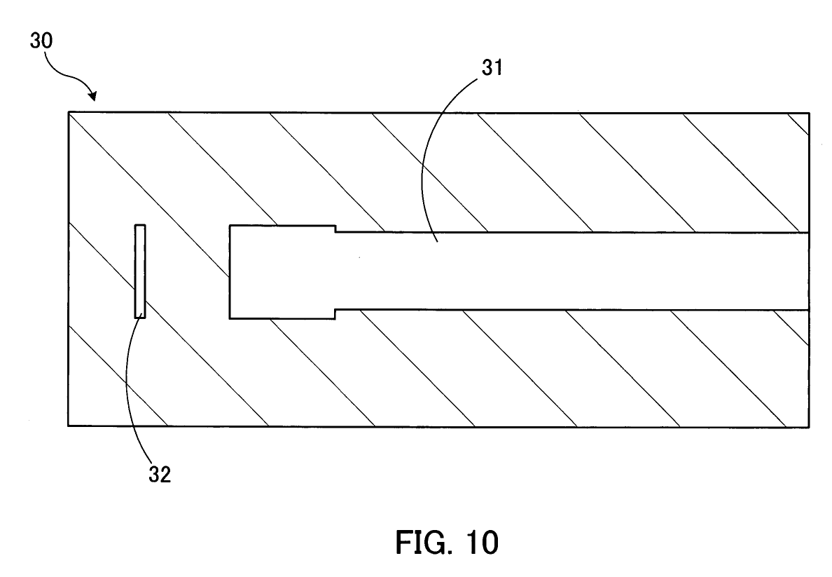

FIG. 10 is a plan view showing the structure of a main portion of a mask on which an isolated pattern is formed.

On a mask 30 shown in FIG. 10, a pattern 31 to be determined corresponding to a circuit pattern formed on a wafer by transferring is formed and an auxiliary pattern 32 is formed near the edge of the pattern 31 to be determined.

By forming the auxiliary pattern 32 near the edge of the isolated pattern 31 to be determined in this way, the amount of a shift in the position of the edge of the pattern 31 to be determined can be determined with great accuracy at proper magnification even if there is no mask pattern around the pattern 31 to be determined.

As has been described in the foregoing, in the present invention, by locating auxiliary patterns near a pattern to be determined used for determining the line length thereof, the amount of a shift in the position of the edge of the pattern to be determined can be determined with great accuracy and the line length of the mask pattern can be found with great accuracy. Accordingly, this method is effective in guaranteeing the line length of a pattern. In addition, the amount of a shift in the position of the edge of a pattern can be controlled strictly, so the number of fabricated devices in which the contact is bad can be reduced. Therefore, high-quality devices can be fabricated.

In the present invention, the auxiliary patterns are located near the mask pattern the line length of which is to be determined, the position of the mask pattern in respect to the auxiliary patterns is determined, and the line length of the mask pattern is determined. As a result, the amount of a shift in the position of the mask pattern from a designed value can be determined with accuracy and the line length of the mask pattern can be determined with great accuracy. This enables the fabrication of high-quality devices.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A mask comprising:
a mask pattern; and
auxiliary patterns located near the mask pattern and used for determining the line length of the mask pattern.

2. The mask according to claim 1, wherein each of the auxiliary patterns is formed near each edge of the mask pattern so that each of the auxiliary patterns will be opposite to each edge of the mask pattern.

3. The mask according to claim 1, wherein the auxiliary patterns are formed so that the shape, line length, and positions of the auxiliary patterns will not exert an influence upon functions which a circuit pattern formed by transferring the mask pattern onto a substrate should have.

4. The mask according to claim 1, wherein when the mask pattern is transferred onto a substrate, the auxiliary patterns are not transferred onto the substrate for reasons of line length.

5. A method for determining the line length of a mask pattern wherein the line length of the mask pattern is found by determining the position of the mask pattern in respect to auxiliary patterns located near the mask pattern.

6. The method for determining the line length of a mask pattern according to claim 5, wherein each of the auxiliary patterns is formed near each edge of the mask pattern so that each of the auxiliary patterns will be opposite to each edge of the mask pattern.

7. The method for determining the line length of a mask pattern according to claim 5, wherein:
the position of the mask pattern in respect to the auxiliary patterns located near the mask pattern is determined; and
the line length of the mask pattern is found on the basis of the difference between the position of the mask pattern and a designed value.

8. The method for determining the line length of a mask pattern according to claim 5, wherein the positions of edges of the mask pattern in respect to the auxiliary patterns are determined in order to determine the position of the mask pattern in respect to the auxiliary patterns.

9. The method for determining the line length of a mask pattern according to claim 5, wherein the distance between the position of the center of gravity of each of the auxiliary patterns and an edge of the mask pattern is determined in order to determine the position of the mask pattern in respect to the auxiliary patterns.

10. The method for determining the line length of a mask pattern according to claim 9, wherein:
the distance between a far edge from an edge of the mask pattern of each of the auxiliary patterns opposite the mask pattern and the edge of the mask pattern is determined;
the distance between a near edge from an edge of the mask pattern of each of the auxiliary patterns opposite the mask pattern and the edge of the mask pattern is determined; and
the distance between the position of the center of gravity of each of the auxiliary patterns and the edge of the mask pattern is determined by calculating the average of the determined distance between the far edge of each of the auxiliary patterns and the edge of the mask pattern and the determined distance between the near edge of each of the auxiliary patterns and the edge of the mask pattern.
